(19) United States
(12) Patent Application Publication
(10) Pub. No.: US 2016/0101975 A1
(43) Pub. Date: Apr. 14, 2016

(54) Resonance Frequency Adjustment Module

(71) Applicant: Murata Manufacturing Co., Ltd., Nagaokakyo-shi (JP)

(72) Inventors: Hidekazu Ono, Hamamatsu-shi (JP); Tsuyoshi OKAMI, Hamamatsu-shi (JP); Nobuaki TSUJI, Hamamatsu-shi (JP); Yuki UEYA, Hamamatsu-shi (JP)

(21) Appl. No.: 14/972,237

(22) Filed: Dec. 17, 2015

Related U.S. Application Data
(63) Continuation of application No. PCT/JP2014/066052, filed on Jun. 17, 2014.

(30) Foreign Application Priority Data
Jun. 19, 2013 (JP) 2013-128999

(51) Int. Cl. B81B 3/00; G01C 19/5712

(52) U.S. Cl. CPC B81B 3/0045; G01C 19/5712; B81B 2203/04; B81B 2203/0127; B81B 2203/0163; B81B 2203/0307; B81B 2203/053

(57) ABSTRACT

A resonance frequency adjustment module is disclosed forming a MEMS sensor for detecting an angular velocity. The resonance frequency adjustment module includes a movable electrode; a fixed electrode facing the movable electrode to form a capacitor; and an elastic body supporting the movable electrode so as to be displaceable in one direction. The movable electrode and the fixed electrode have surfaces facing each other to form a capacitor, and the surface can be inclined to a displacement direction. A region sandwiched between the movable electrode and the fixed electrode has a volume fixed region where the volume is not decreased by movement of the movable electrode.

### CROSS REFERENCE TO RELATED APPLICATIONS

The present application is a continuation of PCT/JP2014/066052 filed Jun. 17, 2014, which claims priority to Japanese Patent Application No. 2013-128999, filed Jun. 19, 2013, the entire contents of each of which are incorporated herein by reference.

### FIELD OF THE INVENTION

The present invention relates to a resonance frequency adjustment module forming a MEMS sensor.

### BACKGROUND

In recent years, an apparatus having a microscopic machine element formed by utilizing the semiconductor manufacturing technique referred to as MEMS (Micro Electro Mechanical Systems) has been developed and implemented as an acceleration sensor and a gyro sensor for detecting the angular velocity of a target body to be measured.

For example, the above-mentioned gyro sensor includes: a vibration drive module supported on a substrate extending in the X-Y direction such that this module can vibrate in the X direction; a moving body connected to this vibration drive module; an electrostatic-capacitance change detection module supported by this moving body so as to be elastically displaceable in the Y direction and serving to detect a displacement amount in the Y direction; and the like.

In such a gyro sensor, the moving body and a movable electrode of the electrostatic-capacitance change detection module supported by this moving body are caused to continuously reciprocate in the X direction by the vibration drive module. Then, the gyro sensor detects, as displacement of the movable electrode in the Y direction, the Coriolis force acting on the movable electrode at the time of rotation of the gyro sensor about the axis in the Z direction perpendicular to the X-Y plane. The movable electrode of the electrostatic-capacitance change detection module is displaced not only by the Coriolis force acting by the angular velocity (or the rotation speed) of the gyro sensor but also by the acceleration of the gyro sensor in the Y direction. Accordingly, the difference between the displacements of the movable electrodes included in two electrostatic-capacitance change detection modules is taken to thereby compensate for the acceleration in the Y direction applied to the gyro sensor, so that only the direction change of the gyro sensor on the X-Y plane is detected (for example, see Japanese Patent Laying-Open No. 2013-96952).

Furthermore, the gyro sensor includes an elastic body that supports the moving body so as to be movable in the X direction. Also, the vibrations of the moving body and the electrostatic-capacitance change detection module in the X direction are restricted by the resonance frequency determined by the spring constant and the mass of this elastic body. Accordingly, there is a proposed resonance frequency adjustment module having an electric spring structure such that the spring constant of the elastic body can be adjusted and the resonance frequency can be controlled.

As such a resonance frequency adjustment module, a resonance frequency adjustment module 51 is proposed, which has a pair of electrodes 52 and 54 facing each other and capable of adjusting the voltage difference, as shown in FIG. 6 (Conventional Example 1). Furthermore, a resonance frequency adjustment module 61 is also proposed, which has a pair of comb-shaped electrodes 62 and 64 arranged so as to engage with each other as shown in FIG. 7 (Conventional Example 2).

However, according to resonance frequency adjustment module 51 of Conventional Example 1, when the pair of electrodes 52 and 54 are displaced in a direction so as to be closer to each other, the air in the space between electrodes 52 and 54 (a space in which a capacitor is formed) is compressed. In this case, the air resistance (damping) by this compression of air is relatively high, which leads to a disadvantage that the Q factor (Quality Factor) decreases and the amplitude lowers. Furthermore, this resonance frequency adjustment module 51 also causes a disadvantage that, when the displacement is increased, electrodes 52 and 54 are brought excessively close to each other, and therefore, brought into the so-called Pull-in state. Particularly, in resonance frequency adjustment module 51 of Conventional Example 1, the electrostatic capacitance needs to be increased in order to expand the adjustment range of the spring constant. For this purpose, electrodes 52 and 54 need to be increased in size or number, which however leads to a significant decrease in the Q factor due to the air resistance, as described above.

Furthermore, in resonance frequency adjustment module 61 of Conventional Example 2, one comb-shaped electrode 64 is formed in a step-like shape in order to achieve a prescribed spring constant without exerting any influence upon displacement of movable electrode 62. Accordingly, the “Pull-in” state as a disadvantage is less likely to occur. However, in this resonance frequency adjustment module 61, electrodes 62 and 64 need to be increased in size or number in order to increase the spring constant and the electrostatic capacitance. Consequently, resonance frequency adjustment module 61 is increased in size, so that the area efficiency deteriorates.

Patent Document 1: Japanese Patent Laying-Open No. 2013-96952.

### SUMMARY OF THE INVENTION

The present invention has been made in light of the above-described circumstances, and aims to provide a resonance frequency adjustment module capable of readily and reliably reducing the air resistance while satisfying the demand for size reduction.

In view of the above-described problems, a resonance frequency adjustment module is disclosed that forms a MEMS sensor detecting an angular velocity. The resonance frequency adjustment module includes a movable electrode having a first facing surface; a fixed electrode having a second facing surface that faces the first facing surface of the movable electrode to form a capacitor with the first facing surface; and an elastic body supporting the movable electrode so as to be displaceable in one direction. The first facing surface of the movable electrode and the second facing surface of the fixed electrode are inclined to a displacement direction of the movable electrode, and a space with a fixed volume is sandwiched between the movable electrode and the fixed electrode is provided. The space has a volume that is fixed irrespective of displacement of the movable electrode.

In this resonance frequency adjustment module, the facing surfaces of the movable electrode and the fixed electrode, which form a capacitor, each are inclined to the displacement direction. The tensile force caused by the electric potential difference acts on the movable electrode and the fixed electrode at their respective inclined facing surfaces. Then, this electric potential difference is adjusted so that a desired spring constant can be achieved. Furthermore, according to this resonance frequency adjustment module, the facing surfaces of the movable electrode and the fixed electrode are inclined, and a region sandwiched between the movable electrode and the fixed electrode has a region in which a volume is not decreased by movement of the movable electrode (which may be hereinafter referred to as a volume fixed region). Accordingly, when the movable electrode is displaced, the air between the facing surfaces can flow along the inclined facing surfaces into the volume fixed region. Therefore, this resonance frequency adjustment module allows reduction in compression and flow of the air, so that the air resistance can be readily and reliably reduced.

As described above, according to the resonance frequency adjustment module of the present invention, a highly precise gyro sensor can be achieved at low cost.

### BRIEF DESCRIPTION OF DRAWINGS

FIG. 1 is a schematic diagram of a resonance frequency adjustment module according to the first embodiment of the present invention.

FIG. 2 is a schematic diagram of a resonance frequency adjustment module according to the second embodiment of the present invention.

FIG. 3 is a schematic diagram of a resonance frequency adjustment module according to the third embodiment of the present invention.

FIG. 4 is a schematic diagram of a resonance frequency adjustment module according to the fourth embodiment of the present invention.

FIG. 5 is a schematic diagram of a resonance frequency adjustment module according to the fifth embodiment of the present invention.

FIG. 6 is a schematic diagram of a resonance frequency adjustment module according to Conventional Example 1.

FIG. 7 is a schematic diagram of a resonance frequency adjustment module according to Conventional Example 2.

### DETAILED DESCRIPTION OF EXEMPLARY EMBODIMENTS

### First Embodiment

Embodiments of a resonance frequency adjustment module of the present invention will be hereinafter described in detail with reference to the accompanying drawings as appropriate.

<Resonance Frequency Adjustment Module>

A resonance frequency adjustment module 1 in FIG. 1 serves as a resonance frequency adjustment module forming a MEMS sensor detecting an angular velocity. This resonance frequency adjustment module 1 includes a movable electrode 2; an elastic body 3 supporting this movable electrode 2 so as to be displaceable in one direction; and a fixed electrode 4 facing movable electrode 2 to form a capacitor. Accordingly, an electric potential difference is applied to movable electrode 2 and fixed electrode 4, so that the tensile force (Coulomb force) acts between the facing surfaces of movable electrode 2 and fixed electrode 4, which form a capacitor. Therefore, by adjusting this electric potential difference, the spring constant of resonance frequency adjustment module 1 can be adjusted.

In this resonance frequency adjustment module 1, fixed electrode 4 is immovably fixed to a substrate (not shown) of the MEMS sensor and movable electrode 2 is fixed to a moving body (not shown). Furthermore, movable electrode 2 is fixed to the moving body via an elastic body 3 and a weight 5. This elastic body 3 supports movable electrode 2 so as to be displaceable in the direction opposite to fixed electrode 4 (in the X direction). Weight 5 is a conceptual representation of a mass of a displacement of resonance frequency adjustment module 1.

Although the materials of fixed electrode 4 and movable electrode 2 are not particularly limited, silicon can be used, for example.

The facing surfaces of movable electrode 2 and fixed electrode 4 are inclined to the displacement direction (the X direction). A region sandwiched between movable electrode 2 and fixed electrode 4 includes a region or space S where a volume does not decrease during movement of movable electrode 2 (which may be hereinafter referred to as a volume fixed region).

Specifically, movable electrode 2 and fixed electrode 4 are arranged so as to face each other in the displacement direction (X direction). Movable electrode 2 includes a base mount 2a; a plurality of projections (in the illustrated example, two) with base portions 2b disposed to protrude from base mount 2a toward fixed electrode 4; and a plurality of first extending or convex portions 2c that each have a triangular shape in plan view and are disposed to protrude from each of these base portions 2b toward fixed electrode 4. Furthermore, fixed electrode 4 includes a base mount 4a; a plurality of projections (in the illustrated example, three) with base portions 4b disposed to protrude from this base mount 4a toward movable electrode 2; and a plurality of second extending or convex portions 4c that each have a triangular shape in plan view and are disposed to protrude from each of these base portions 4b toward movable electrode 2 such that its vertex is located between the vertices of the plurality of first convex portions 2c. The facing surfaces of first convex portion 2c and second convex portion 4 each inclined to the X direction form a capacitor, and the capacitance of this capacitor changes in accordance with displacement of movable electrode 2 in the X direction. Furthermore, a region between the plurality of base portions 2b of movable electrode 2 and a region between the plurality of base portions 4b of fixed electrode 4 each function as volume fixed region S described above. Thereby, when movable electrode 2 is displaced, the air between the facing surfaces of first convex portion 2c and second convex portion 4c can flow along the above-described inclined facing surfaces into volume fixed region S.

The facing surfaces of first convex portion 2c and second convex portion 4c are inclined to the displacement direction (the X direction) as described above, and arranged so as to be approximately parallel to each other. In this case, the lower limit of an angle of inclination a of each facing surface to the displacement direction (X direction) is preferably 5 degrees and more preferably 10 degrees. The upper limit of the angle of inclination a is preferably 30 degrees and more preferably 20 degrees. In the case where the angle of inclination a is less than the above-mentioned lower limit, the tensile force acting in the displacement direction (X direction) between movable electrode 2 and fixed electrode 4 is reduced. Thus, movable electrode 2 needs to be increased in number and size for achieving a desired spring constant, which may be contrary to the demand for size reduction of the apparatus. In contrast, in the case where the angle of inclination a exceeds the above-mentioned upper limit, the air between the facing surfaces may be less likely to flow into volume fixed region S when movable electrode 2 is displaced.

As described above, the angle of inclination of each facing surface to the displacement direction is preferably 5 degrees or more and 30 degrees or less. If the angle of inclination falls within the above-mentioned range, a desired spring constant can be readily and reliably achieved while compression and flow of the air in this resonance frequency adjustment module can be readily and reliably reduced.

The distance between the facing surfaces of first convex portion 2c of movable electrode 2 and second convex portion 4c of fixed electrode 4 can be designed as appropriate in accordance with the electrostatic capacitance required for adjustment of the spring constant, and for example can be set at 0.5 μm or more and 5 μm or less.

Furthermore, assuming that the plan view area of the region forming a capacitor between one surface of first convex portion 2c and the facing surface of second convex portion 4c that faces this one surface (which will be hereinafter also referred to as a region between the facing surfaces) is defined as A1 and that the plan view area of one space or fixed region S adjacent to this region between the facing surfaces is defined as A2, the lower limit of the ratio of A2 to A1 is preferably one time, and more preferably two times. In the case where the above-mentioned ratio is less than the lower limit, the air between the facing surfaces may be less likely to flow into volume fixed region S when movable electrode 2 is displaced. In addition, the upper limit of the above-mentioned ratio is preferably ten times, and more preferably eight times. The ratio exceeding the upper limit may be contrary to the demand for size reduction of the apparatus.

<Gyro Sensor>

Resonance frequency adjustment module 1 is used for a gyro sensor (MEMS sensor) as described above. This gyro sensor can be configured to include, for example, two moving bodies arranged in the X direction and supported on a substrate extending in the X-Y direction so as to be movable in the X direction; two electrostatic-capacitance change detection modules supported by the moving bodies such that the movable electrode for detection can be displaced in the Y direction; and a vibration drive module causing each moving body to reciprocate in the X direction. In this resonance frequency adjustment module 1, fixed electrode 4 is fixed to the substrate and movable electrode 2 is fixed to the moving body.

In this resonance frequency adjustment module 1, the facing surfaces of movable electrode 2 and fixed electrode 4 each are inclined to the displacement direction, and the tensile force acts on movable electrode 2 and fixed electrode 4 at their respective inclined facing surfaces. Thus, the electric potential difference is adjusted so that a desired spring constant can be obtained. Accordingly, the resonance frequencies of the moving body and the electrostatic-capacitance change detection module can be controlled.

Furthermore, in this resonance frequency adjustment module 1, the space between base portions 2b and 4b serves to function as the above-described volume fixed region. Accordingly, when movable electrode 2 is moved close to fixed electrode 4, the air between these facing surfaces can flow along the above-mentioned inclined facing surfaces into the volume fixed region. Therefore, according to this resonance frequency adjustment module 1, in the electrostatic-capacitance change detection unit, compression and flow of the air are reduced, so that the air resistance can be readily and reliably reduced. Consequently, noise can be appropriately suppressed.

Furthermore, the size of this resonance frequency adjustment module 1 can be reduced as compared with a conventional design having a comb-shaped electrode (Conventional Example 2), so that the demand for size reduction of the apparatus can also be appropriately satisfied.

In the resonance frequency adjustment module of the present embodiment, the movable electrode and the fixed electrode are arranged so as to face each other in the displacement direction; the movable electrode has, on the side close to the fixed electrode, a plurality of base portions and a plurality of first convex portions. The plurality of first convex portions each are formed in a triangular shape in plan view and disposed to protrude from each of the base portions toward the fixed electrode; and the fixed electrode has, on the side close to the movable electrode, one or more base portions and one or more second convex portions. The one or more second convex portions each are formed in a triangular shape in plan view and disposed to protrude from each of the base portions toward the movable electrode such that its vertex is located between the vertices of the plurality of first convex portions.

By configuring this resonance frequency adjustment module as described above, a desired spring constant can be readily and reliably achieved at the surfaces of the first convex portion and the second convex portion that face each other, and also, a volume fixed region can be readily and reliably formed between the base portions so that compression and flow of the air can be reduced.

### Second Embodiment

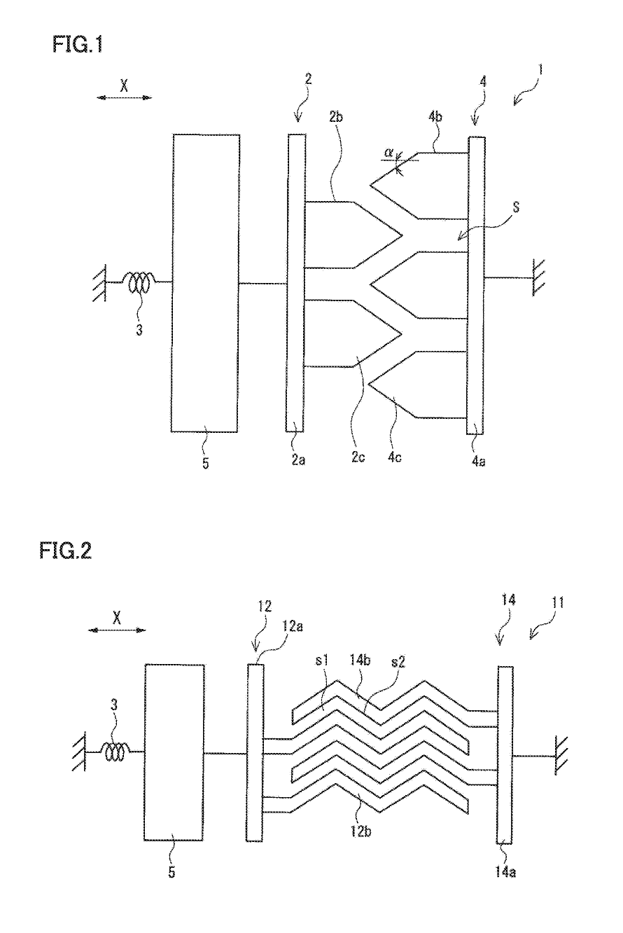

Then, a resonance frequency adjustment module 11 in the second embodiment will be hereinafter described with reference to FIG. 2. It is to be noted that resonance frequency adjustment module 11 in the second embodiment will be described using the same reference characters with regard to the functions or structures identical to those included in resonance frequency adjustment module 1 of the first embodiment, and the description thereof may not be repeated.

As shown in FIG. 2, the resonance frequency adjustment module 11 includes a movable electrode 12 that is supported by an elastic body 3 so as to be displaceable in the X direction, and includes a base mount 12a, and a plurality of (in the illustrated example, two) projections 12b extending from this base mount 12a to one side in the displacement direction. Also, each projection 12b has a facing surface formed to bend at regular intervals alternately in opposite directions (in a zigzag pattern) in plan view in the extending direction. Specifically, projection 12b is configured of a flat plate-shaped member formed to extend from base mount 12a toward fixed electrode 14 and bend in an almost V shape several times (two times in the illustrated example), as shown in FIG. 2. In other words, movable electrode 12 has a facing surface formed of a mountain fold portion and a valley fold portion that are arranged side by side each in a fixed length in the direction in which the projection 12b extends. In addition, fixed electrode 14 is fixed to the substrate or the like of the MEMS sensor.

Furthermore, fixed electrode 14 has a surface facing the facing surface of movable electrode 12 at a fixed distance. Specifically, fixed electrode 14 has a base mount 14a and a plurality of (in the illustrated example, two) projections 14b extending from this base mount 14a toward the other side in the displacement direction. Each projection 14b of fixed electrode 14 is approximately identical in shape to projection 12b of movable electrode 12. The surface of projection 12b of movable electrode 12 and the surface of projection 14b of fixed electrode 14 face each other to form a capacitor. These facing surfaces are inclined to the displacement direction. In this case, the volume between projection 12b of movable electrode 12 and projection 14b of fixed electrode 14 is not changed even if movable electrode 12 is displaced. Accordingly, the region between projections 12b and 14b functions as a volume fixed region. In other words, for example, in the case where movable electrode 12 moves closer to fixed electrode 14, movable electrode 12 and fixed electrode 14 are located close to each other to reduce the volume therebetween in a region s1 on one surface of the V-shaped plane. In contrast, movable electrode 12 and fixed electrode 14 are located away from each other to increase the volume therebetween in a region s2 on the other surface of the V-shaped plane. Thus, between projections 12b and 14b on the whole, the volume between the electrodes is not changed. Accordingly, the air in region s1 in which projections 12b and 14b are located close to each other upon displacement of movable electrode 12 can flow into region s2 in which projections 12b and 14b are located away from each other.

In addition, as to the angle of inclination of the facing surfaces of projections 12b and 14b to the displacement direction (the X direction), as in the first embodiment, the lower limit is preferably 5 degrees and more preferably 10 degrees while the upper limit is preferably 30 degrees and more preferably 20 degrees.

As described above, if the angle of inclination is 5 degrees or more and 30 degrees or less, a desired spring constant can be readily and reliably achieved while compression and flow of the air in the resonance frequency adjustment module can be readily and reliably reduced.

In the resonance frequency adjustment module in the present embodiment, the movable electrode has a projection extending to one side in the displacement direction, this projection has a facing surface formed so as to bend at regular intervals alternately in opposite directions in plan view in the extending direction, and the fixed electrode has a surface facing this facing surface at a fixed distance.

By configuring this resonance frequency adjustment module as described above, a desired spring constant can be readily and reliably achieved at the surfaces of the projections of the movable electrode and the fixed electrode that face each other, and also, a volume fixed region can be readily and reliably formed between the projections so that compression and flow of the air can be reduced.

### Third Embodiment

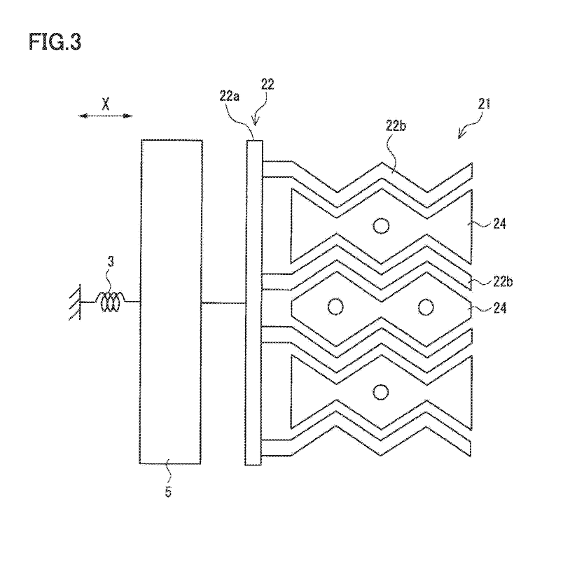

Then, a resonance frequency adjustment module 21 in the third embodiment will be hereinafter described with reference to FIG. 3. It is to be noted that resonance frequency adjustment module 21 in the third embodiment will be described using the same reference characters with regard to the functions or structures identical to those included in resonance frequency adjustment module 1 or 11 of the first or second embodiment, and the description thereof may not be repeated.

In resonance frequency adjustment module 21 in FIG. 3, as in the second embodiment, a movable electrode 22 is supported by an elastic body 3 so as to be displaceable in the X direction, and has a base mount 22a and a plurality of (in the illustrated example, four) projections 22b extending from this base mount 22a to one side in the displacement direction. Each projection 22b has a facing surface formed so as to bend at regular intervals alternately in opposite directions (in a zigzag pattern) in plan view in the extending direction. In other words, movable electrode 22 has a facing surface formed of a mountain fold portion and a valley fold portion that are arranged side by side each in a fixed length in the direction in which projection 22b extends. Furthermore, fixed electrode 24 has a surface facing the facing surface of movable electrode 22 at a fixed distance. These facing surfaces inclined to the displacement direction form a capacitor. In addition, fixed electrode 24 is fixed by a via to the substrate or the like of the MEMS sensor.

In resonance frequency adjustment module 21 in FIG. 3, fixed electrode 24 has a plurality of (in the illustrated example, three) polygon-shaped bodies arranged between a plurality of projections 22b of movable electrode 22. Also, each polygon-shaped body has a shape formed of a plurality of rhombuses or a shape formed of a plurality of rhombuses partially connected to each other, in plan view, so as to face the facing surface of movable electrode 22. In addition, in resonance frequency adjustment module 1 in FIG. 3, the volume between this polygon-shaped body and projections 22b of movable electrode 22 is not changed even when movable electrode 22 is displaced. Accordingly, the space between the polygon-shaped body and projections 22b functions as a volume fixed region.

In addition, as to the angle of inclination of the facing surfaces of projections 22b and fixed electrode 24 to the displacement direction (X direction), as in the first embodiment, the lower limit is preferably 5 degrees and more preferably 10 degrees while the upper limit is preferably 30 degrees and more preferably 20 degrees.

As described above, if the angle of inclination is 5 degrees or more and 30 degrees or less, a desired spring constant can be readily and reliably achieved while compression and flow of the air in the resonance frequency adjustment module can be readily and reliably reduced.

Furthermore, by configuring this resonance frequency adjustment module as described above, a desired spring constant can be readily and reliably achieved at the facing surfaces of the projections of the movable electrode and the fixed electrode that face each other, and also, a volume fixed region can be readily and reliably formed between the projections so that compression and flow of the air can be reduced.

### Fourth Embodiment

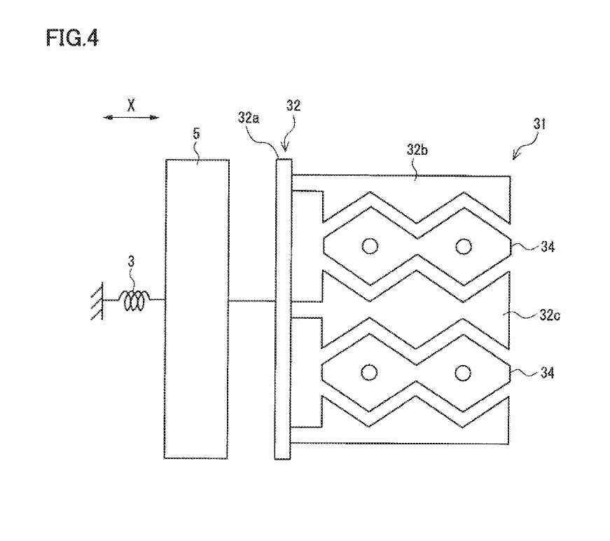

Then, a resonance frequency adjustment module 31 in the fourth embodiment will be hereinafter described with reference to FIG. 4. It is to be noted that resonance frequency adjustment module 31 in the fourth embodiment will be described using the same reference characters with regard to the functions or structures identical to those included in resonance frequency adjustment module 1, 11 or 21 in the first, second or third embodiment, and the description thereof may not be repeated.

In resonance frequency adjustment module 31 in FIG. 4, as in the second and third embodiments, movable electrode 32 is supported by an elastic body 3 so as to be displaceable in the X direction, and has a base mount 32a, and a plurality of (in the illustrated example, a total of three) projections 32b and 32c extending from this base mount 32a to one side in the displacement direction. These projections 32b and 32c each have a facing surface formed so as to bend at regular intervals alternately in opposite directions (in a zigzag pattern) in plan view in the extending direction. In other words, movable electrode 32 has a facing surface formed of a mountain fold portion and a valley fold portion that are arranged side by side each in a fixed length in the direction in which projection 32b extends. Furthermore, fixed electrode 34 has a surface facing the facing surface of movable electrode 32 at a fixed distance to thereby form a capacitor. These facing surfaces are inclined to the displacement direction. In addition, fixed electrode 34 is fixed by a via to the substrate or the like of the MEMS sensor.

In resonance frequency adjustment module 31 in FIG. 4, fixed electrode 34 has a plurality of (in the illustrated example, two) polygon-shaped bodies arranged between the plurality of projections 32b and 32c of movable electrode 32, as in the third embodiment.

Projections 32b and 32c of movable electrode 32 each have a polygonal shape in plan view so as to face the facing surface of the above-mentioned fixed electrode 34. Specifically, projection 32b located at the end (the upper portion and the lower portion in FIG. 4) has one surface (for example, the upper surface of the upper projection) formed to be smooth and the other surface formed in a polygonal shape so as to extend along the facing surface of the above-mentioned polygonal shape. Furthermore, projection 32c located in the center has surfaces each formed in a polygonal shape so as to extend along the facing surface of the polygon-shaped body. In resonance frequency adjustment module 31 in FIG. 4, the volume between the polygon-shaped body of fixed electrode 34 and each of projections 32b and 32c of movable electrode 32 is not changed even when movable electrode 32 is displaced. Accordingly, the space between the polygon-shaped body and each of projections 32b and 32c functions as a volume fixed region.

In addition, as to the angle of inclination of the facing surface of each of projections 32b and 32c and fixed electrode 34 to the displacement direction (X direction), as in the first embodiment, the lower limit is preferably 5 degrees and more preferably 10 degrees while the upper limit is preferably 30 degrees and more preferably 20 degrees.

As described above, if the angle of inclination is 5 degrees or more and 30 degrees or less, a desired spring constant can be readily and reliably achieved while compression and flow of the air in the resonance frequency adjustment module can be readily and reliably reduced.

Furthermore, by configuring this resonance frequency adjustment module as described above, a desired spring constant can be readily and reliably achieved at the surfaces of the projections of the movable electrode and the fixed electrode that face each other, and also, a volume fixed region can be readily and reliably formed between the projections so that compression and flow of the air can be reduced.

### Fifth Embodiment

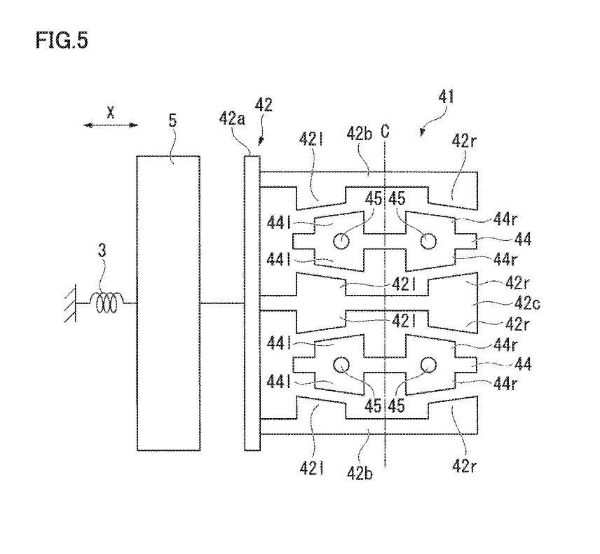

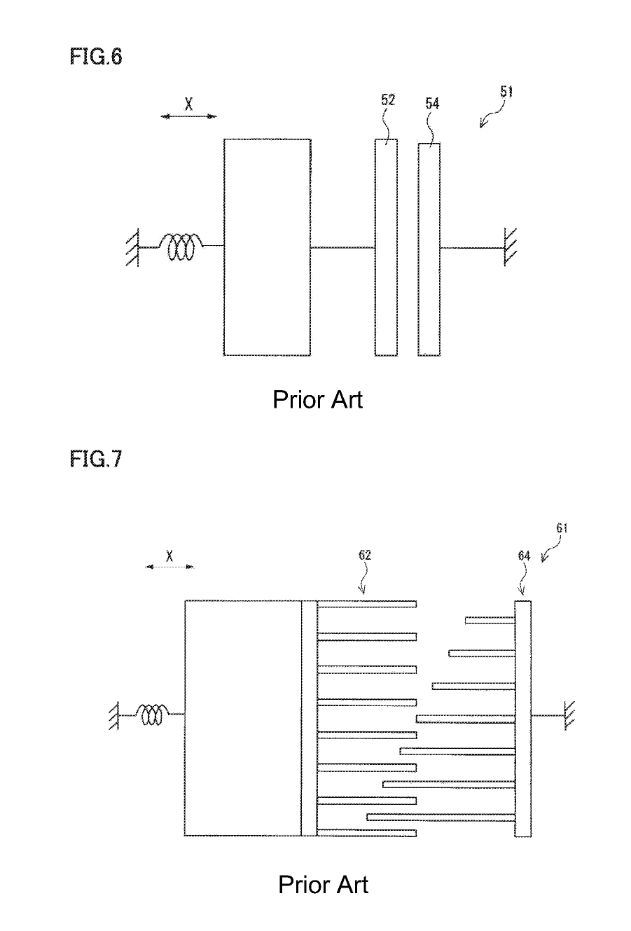

Then, a resonance frequency adjustment module 41 in the fifth embodiment will be hereinafter described with reference to FIG. 5. It is to be noted that resonance frequency adjustment module 41 in the fifth embodiment will be described using the same reference characters with regard to the functions or structures identical to those included in resonance frequency adjustment module 1, 11, 21, or 31 of the first, second, third or fourth embodiment, and the description thereof may not be repeated.

In resonance frequency adjustment module 41 in FIG. 5, as in the second to fourth embodiments, movable electrode 42 is supported by an elastic body 3 so as to be displaceable in the X direction, and has a base mount 42a and a plurality of (in the illustrated example, a total of three) projections 42b and 42c extending from this base mount 42a to one side in the displacement direction. These projections 42b and 42c each have a plurality of convex-shaped teeth 42r and 42l that are formed at regular intervals in the extending direction and face fixed electrode 44. Fixed electrode 44 has convex-shaped teeth 44r and 44l provided at regular intervals at its facing surface that faces the surface of movable electrode 42 having convex-shaped teeth formed thereon, thereby forming a capacitor between fixed electrode 44 and movable electrode 42. Movable electrode 42 and fixed electrode 44 are provided with convex-shaped teeth 42r and 44r, respectively, having facing surfaces that are parallel to each other and inclined to the displacement direction of movable electrode 42, and also provided with convex-shaped teeth 42l and 44l, respectively, having facing surfaces that are parallel to each other and inclined to the displacement direction of movable electrode 42. Convex-shaped teeth 42r, 44r and convex-shaped teeth 42l, 44l are arranged symmetrically with respect to a center line C. Therefore, the inclinations of convex-shaped teeth 42r and 44r on a pair of facing surfaces are symmetrical to the inclinations of convex-shaped teeth 42l and 44l, respectively, with respect to a symmetrical line C. Fixed electrode 44 is fixed by a via 45 to the substrate or the like of the MEMS sensor.

In resonance frequency adjustment module 41 in FIG. 5, convex-shaped teeth 44r and 44l of fixed electrode 44 are almost identical in width in the displacement direction to convex-shaped teeth 42r and 44l of movable electrode 42. Furthermore, the distance between convex-shaped teeth 44r and 44l formed on fixed electrode 44 is less than the distance between convex-shaped teeth 42r and 42l formed on movable electrode 42. In the stationary state, the left end of convex-shaped tooth 42r faces almost the center portion of convex-shaped tooth 44r in the displacement direction while the right end of convex-shaped tooth 42l faces almost the center portion of convex-shaped tooth 44l in the displacement direction. In other words, the position at which convex-shaped teeth 44r and 42r faces each other in the displacement direction and the position at which convex-shaped teeth 44l and 42l face each other in the displacement direction are shifted in phase.

In the case where movable electrode 42 is displaced in the X direction, the total area of the area in which convex-shaped teeth 44r and 42r face each other and the area in which convex-shaped teeth 44l and 42l face each other is approximately constant. Specifically, when movable electrode 42 is displaced to the right side in FIG. 5, the area in which convex-shaped teeth 44r and 42r face each other decreases, whereas the area in which convex-shaped teeth 44l and 42l face each other increases accordingly. In contrast, when movable electrode 42 is displaced to the left side in FIG. 5, the area in which convex-shaped teeth 44r and 42r face each other increases, whereas the area in which convex-shaped teeth 44l and 42l face each other decreases accordingly. Therefore, also when movable electrode 42 is displaced in the X direction, the area of the convex-shaped tooth of movable electrode 42 and the area of the convex-shaped tooth of fixed electrode 44 that face each other are the same on the whole, that is, the volume between the electrodes is fixed on the whole. Consequently, a volume unchanged (fixed) region is to be provided between electrodes, that is, between movable electrode 42 and fixed electrode 44.

As to the angle of inclination of the facing surfaces of each of convex-shaped tooth of movable electrode 42 and the convex-shaped tooth of fixed electrode 44 to the displacement direction (X direction), the lower limit is preferably 5 degrees and more preferably 10 degrees while the upper limit is preferably 30 degrees and more preferably 20 degrees.

As described above, if the angle of inclination is 5 degrees or more and 30 degrees or less, a desired spring constant can be readily and reliably achieved while compression and flow of the air in the resonance frequency adjustment module can be readily and reliably reduced.

Furthermore, by configuring this resonance frequency adjustment module as described above, a desired spring constant can be readily and reliably achieved at the surfaces of the projections of the movable electrode and the fixed electrode that face each other, and also, a volume fixed region can be readily and reliably formed between the projections so that compression and flow of the air can be reduced.

### Other Embodiments

The resonance frequency adjustment module of the present invention is not limited to the above-described embodiments. Namely, as long as the facing surfaces of the movable electrode and the fixed electrode each are inclined to the displacement direction, the present invention is not particularly limited, but the first convex portion, the second convex portion, the projection, and the like as in the above-described embodiments are not indispensable constituent elements of the present invention.

Furthermore, the first convex portion, the second convex portion, the projection, and the like are not limited in number to those described in the above-described embodiments, but can be set at any number.

Furthermore, also in the case where the movable electrode and the fixed electrode have the first convex portion and the second convex portion, respectively, the present invention is not limited to the configuration in the above-described first embodiment, but can employ the first convex portion and the second convex portion formed in various shapes. Furthermore, also in the case where the movable electrode has the above-described projection, the present invention is not limited to the configurations of the above-described second to fourth embodiments, but can employ any movable electrodes formed in various shapes.

As described above, since the resonance frequency adjustment module of the present invention can readily and reliably reduce the air resistance while satisfying the demand for size reduction, it can be suitably used as a component of a gyro sensor for a portable terminal and the like.

### REFERENCE SIGNS LIST

1, 11, 21, 31, 41 resonance frequency adjustment module, 2, 12, 22, 32, 42 movable electrode, 2a, 12a, 22a, 32a, 42a base mount, 2b base portion, 2c first convex portion, 3 elastic body, 4, 14, 24, 34, 44 fixed electrode, 4a, 14a base mount, 4b base portion, 4c second convex portion, 5 weight, 12b, 14b, 22b, 32b, 32c, 42c projection.

1. A resonance frequency adjustment module forming a MEMS sensor for detecting an angular velocity, the resonance frequency adjustment module comprising:
a movable electrode having a first surface and a plurality of first projections protruding from the first surface;
a fixed electrode having a second surface and a plurality of second projections protruding from the second surface toward the first surface and interposed between the plurality of first projections, respectively, where the second surface of the fixed electrode faces the first surface of the movable electrode to form a capacitor with the first surface; and
an elastic body supporting the movable electrode such that the movable electrode is displaceable relative to the fixed electrode,
wherein each of the first projections includes a base and an extending portion having a surface inclined relative to the first surface,
wherein each of the second projections includes a surface parallel to the surface of the extending portion of an adjacent first projection, and
wherein a fixed space is defined between the movable electrode and the fixed electrode and the fixed space has a volume that is fixed irrespective of displacement of the movable electrode.

2. The resonance frequency adjustment module according to claim 1, wherein an angle of inclination of the surfaces of each of the first and second projections is 5 degrees or more and 30 degrees or less relative to the respective first and second surfaces.

3. The resonance frequency adjustment module according to claim 1, wherein the movable electrode and the fixed electrode are arranged to face each other in a displacement direction of the movable electrode.

4. The resonance frequency adjustment module according to claim 1,
wherein each of the extending portions of the plurality of first projections of the movable electrode is convex having a triangular shape in a plan view of the resonance frequency adjustment module, and
wherein each of the second projections of the fixed electrode includes a base and an extending portion interposed between the extending portions of the plurality of first projections, respective, and of the extending portions of the plurality of second projections of the fixed electrode is convex having a triangular shape in a plan view of the resonance frequency adjustment module.

5. The resonance frequency adjustment module according to claim 1, wherein the triangular shape of the extending portions of each of the plurality of second projections has a vertex disposed between vertices of the convex portions of a pair of adjacent first projections of the movable electrode.

6. The resonance frequency adjustment module according to claim 1, wherein each of the extending portions of the plurality of first projections comprises a mountain fold portion and a valley fold portion arranged side by side each in a fixed length in a direction extending towards the second surface of the fixed electrode, and the surface of each of the second projections faces the mountain fold portion and the valley fold portion of the adjacent first projection at a fixed distance.

7. The resonance frequency adjustment module according to claim 1, wherein the fixed space is defined between the respective mountain fold and valley fold portions of the plurality of first projections and the surfaces the second projections.

8. The resonance frequency adjustment module according to claim 1, wherein the fixed space is defined between respective bases of adjacent second projections protruding from the second surface of the fixed electrode.

9. The resonance frequency adjustment module according to claim 1, further comprising a weight disposed between the elastic body and the movable electrode.

10. A resonance frequency adjustment module forming a MEMS sensor for detecting an angular velocity, the resonance frequency adjustment module comprising:
a movable electrode having a first surface and a plurality of projections protruding from the first surface;
a fixed electrode having a plurality of polygon-shaped bodies each disposed between a pair of the plurality of projections of the movable electrode; and
an elastic body supporting the movable electrode such that the movable electrode is displaceable relative to the fixed electrode,
wherein each of the plurality of projections includes a base and an extending portion having at least one surface inclined relative to the first surface,
wherein each of the plurality of polygon-shaped bodies has a first side surface facing and parallel to the at least one surface of the extending portion of a first projection of the respective pair of projections, and a second side surface facing and parallel to the at least one surface of the extending portion of a second projection of the respective pair of projections, and
wherein a fixed space is defined between the movable electrode and the fixed electrode and the fixed space has a volume that is fixed irrespective of displacement of the movable electrode.

11. The resonance frequency adjustment module according to claim 10, wherein the fixed electrode is coupled to a substrate of the MEMS sensor by at least one via.

12. The resonance frequency adjustment module according to claim 10, wherein an angle of inclination of the at least one surfaces of each of the extending portions of the plurality of projections is 5 degrees or more and 30 degrees or less relative to the respective first surface of the movable electrode.

13. The resonance frequency adjustment module according to claim 10, wherein each of the extending portions of the plurality of projections comprises a mountain fold portion and a valley fold portion arranged side by side each in a fixed length in a direction extending towards the fixed electrode.

14. The resonance frequency adjustment module according to claim 10, wherein the fixed space is defined between respective bases of adjacent projections protruding from the first surface of the movable electrode.

15. The resonance frequency adjustment module according to claim 10, further comprising a weight disposed between the elastic body and the movable electrode.

16. A resonance frequency adjustment module forming a MEMS sensor for detecting an angular velocity, the resonance frequency adjustment module comprising:
a movable electrode having a first surface and a plurality of projections protruding from the first surface, where each of the plurality of projections includes a base and a plurality of first convex-shaped teeth arranged at regular intervals side by side in a direction in which the respective projection extends;
a fixed electrode having a plurality of bodies each disposed between a pair of the plurality of projections of the movable electrode, where each of the plurality of bodies has a plurality of second convex-shaped teeth that face the first convex-shaped teeth of adjacent projections at a fixed distance; and
an elastic body supporting the movable electrode such that the movable electrode is displaceable relative to the fixed electrode,
wherein a fixed space is defined between the movable electrode and the fixed electrode and the fixed space has a volume that is fixed irrespective of displacement of the movable electrode.

17. The resonance frequency adjustment module according to claim 16, wherein the fixed electrode is coupled to a substrate of the MEMS sensor by at least one via.

18. The resonance frequency adjustment module according to claim 16, wherein an angle of inclination of surfaces of each of the plurality of first and second convex-shaped teeth is 5 degrees or more and 30 degrees or less relative to the respective first surface of the movable electrode.

19. The resonance frequency adjustment module according to claim 16, wherein the fixed space is defined between respective bases of adjacent projections protruding from the first surface of the movable electrode.

20. The resonance frequency adjustment module according to claim 16, further comprising a weight disposed between the elastic body and the movable electrode.
